(19) United States
(12) Patent Application Publication
(10) Pub. No.: US 2019/0330734 A1
(43) Pub. Date: Oct. 31, 2019

(54) METHOD OF COATING HEAT TRANSFER COMPONENTS TO IMPART SUPERHYDROPHOBICITY

(71) Applicant: The Board of Trustees of the University of Illinois, Urbana, IL (US)

(72) Inventors: Nenad Miljkovic, Urbana, IL (US); Kalyan S. Boyina, Urbana, IL (US); Shreyas Chavan, Urbana, IL (US)

(21) Appl. No.: 16/393,048

(22) Filed: Apr. 24, 2019

Related U.S. Application Data
(60) Provisional application No. 62/662,354, filed on Apr. 25, 2018.

(51) Int. Cl. C23C 16/02; C23C 8/02; C23C 8/42; F28F 17/00

(52) U.S. Cl. CPC C23C 16/0227; C23C 8/02; F28F 2245/04; C23C 16/0272; F28F 17/005; C23C 8/42

(57) ABSTRACT

A method for coating heat transfer components to impart superhydrophobicity comprises conveying one or more heat transfer components to a cleaning station, where the one or more heat transfer components are cleaned with an organic solvent. After the cleaning, the one or more heat transfer components are conveyed to a nanostructuring station and immersed in hot water for surface oxidation and roughening. After the immersion in hot water, the one or more heat transfer components are conveyed to a functionalization station and exposed to a heated precursor vapor comprising a hydrophobic species. During the exposure, the hydrophobic species is deposited on roughened surfaces of the one or more heat transfer components, thereby forming a superhydrophobic coating. Prior to being conveyed to the cleaning station, the one or more heat transfer components may be attached to an automated conveyor system positioned to traverse the cleaning, nanostructuring, and functionalization stations.

### RELATED APPLICATION

The present patent document claims the benefit of priority under 35 U.S.C. § 119(e) to U.S. Provisional Patent Application No. 62/662,354, which was filed on Apr. 25, 2018, and is hereby incorporated by reference in its entirety.

### TECHNICAL FIELD

The present disclosure relates generally to surface coating technology more specifically to a method to impart superhydrophobicity to heat transfer components.

### BACKGROUND

Air-coupled heat exchangers are widely used as evaporators in heat pumps and refrigeration systems. These components are susceptible to frost formation when they operate at low temperatures because natural water vapor in the air can condense and freeze or ablimate on the external surface. Frost formation on heat transfer components, such as air-source heat pump evaporators, can result in drastic efficiency penalties. The performance reduction is a result of the insulating nature of ice and the increased fan power required to pump air through the constricted channels between frosted fins. Furthermore, the need to defrost adds appreciable energy use to the system. Recently, researchers have made attempts to prepare superhydrophobic surfaces to inhibit frost formation. However, these efforts are plagued by hard-to-scale fabrication techniques, costly manufacturing methods and/or unrepresentative surface materials.

### SUMMARY

A semi-continuous method to coat large-size heat transfer components to impart superhydrophobicity and prevent frosting has been developed. The method comprises conveying one or more heat transfer components to a cleaning station, where the one or more heat transfer components are cleaned with an organic solvent. After the cleaning, the one or more heat transfer components are conveyed to a nanostructuring station and immersed in hot water for surface oxidation and roughening. After the immersion in hot water, the one or more heat transfer components are conveyed to a functionalization station and exposed to a heated precursor vapor comprising a hydrophobic species. During the exposure, the hydrophobic species is deposited on roughened surfaces of the one or more heat transfer components, thereby forming a superhydrophobic coating. Prior to being conveyed to the cleaning station, the one or more heat transfer components may be attached to an automated conveyor system positioned to traverse the cleaning, nanostructuring, and functionalization stations.

### BRIEF DESCRIPTION OF THE DRAWINGS

FIGS. 1A-1H show exemplary process steps to impart hydrophobicity to one or more heat transfer components, where an individual heat exchanger is shown and some process steps may be optional.

FIG. 2 is a plot of average overall heat transfer coefficient versus time for heat transfer components having superhydrophobic (top data) and unaltered (bottom data) surfaces.

FIGS. 3A-3C show scanning electron microscopy (SEM) images of unaltered (3A) and superhydrophobic surfaces (3B-3C, different magnifications).

FIGS. 3D and 3E show images of water droplets on the unaltered and superhydrophobic surfaces of FIGS. 3A-3C, showing advancing contact angles of 106±19° and 156±13°, respectively.

FIG. 4 is a plot of total heat transfer rates of unaltered, superhydrophilic and superhydrophobic heat exchangers when the coolant enters at −9.6° C.±0.1° C. and the air enters at 47.4° C.±2%.

FIG. 5 shows frosting and defrosting times for the superhydrophobic and unaltered heat exchangers (top and bottom bars for each data set, respectively), where the superhydrophobic heat exchanger exhibits a lower defrosting time and higher heat transfer over a longer time duration.

### DETAILED DESCRIPTION

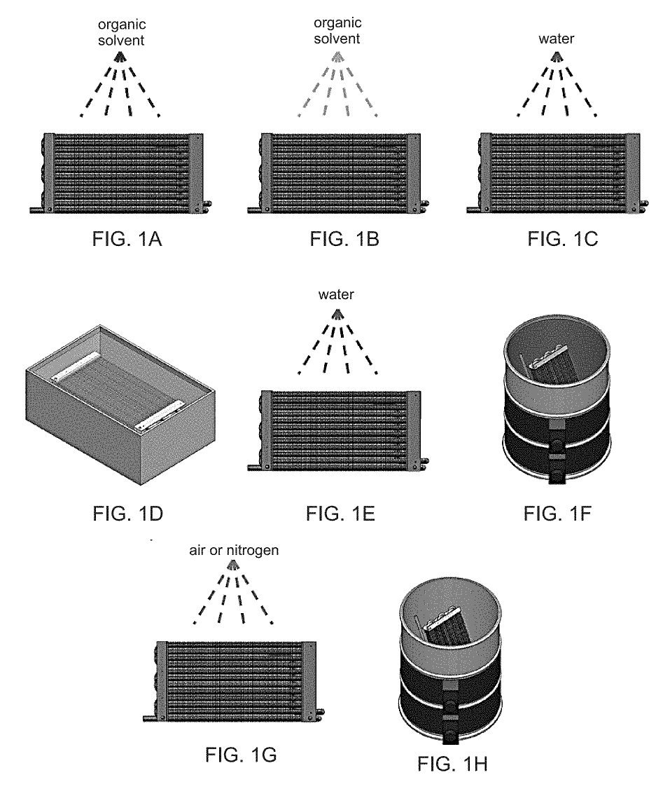

FIGS. 1A-1H illustrate exemplary steps in a method to impart superhydrophobicity to heat exchangers in order to delay or prevent frosting during use. Using this approach, durable superhydrophobic coatings may be applied to large-size, fully-assembled heat exchangers, although the method may be more generally applicable to any metal-based component where superhydrophobicity would be beneficial. Accordingly, the method is described below with respect to a “heat transfer component,” which may be understood to be a heat exchanger for use in residential, automotive, aerospace, marine or other industrial applications, or another metal-based component. In addition to resistance to frosting, the hydrophobicity imparted during the process may lead to an improved overall heat transfer coefficient for the component. Also, due to the surface nanostructuring that takes place prior to application of the superhydrophobic coating, the heat transfer components may exhibit increased corrosion resistance.

The method includes what may be described as cleaning, nanostructuring, and functionalization steps (explained below) that can be applied to a series of individual heat transfer components or to multiple batches of heat transfer components in a semi-continuous process. The method is described as semi-continuous since the heat transfer components may be conveyed without stopping or halted only briefly at treatment stations (e.g., cleaning, nanostructuring, and/or functionalization stations) while undergoing processing. The method may be carried out in a sealed or semi-sealed room, in ambient conditions. In other words, the method may be carried out in air at atmospheric pressure and room temperature (e.g., 18-25° C.), except where otherwise required during the process.

Referring to FIGS. 1A-1C, the method includes conveying one or more heat transfer components to a cleaning station for cleaning with an organic solvent, such as acetone and/or ethanol, normally followed by rinsing with water. During the cleaning step, organic and/or inorganic contaminants are removed from surfaces of the one or more heat transfer components, which may comprise a metal such as aluminum, titanium, iron, chromium, nickel, molybdenum and/or copper (e.g., an aluminum alloy, titanium alloy and/or iron alloy such as stainless steel). For example, the heat transfer component(s) may comprise a 3xxx, 5xxx, 6xxx or 7xxx series aluminum alloy, such as a 3003, 5054, 6061, and/or 7075 aluminum alloy. Individually, the one or more heat transfer components may be large-size components having a length (long dimension) exceeding 50 cm.

The “conveying” of the one or more heat transfer components referred to above and throughout this disclosure may be carried out manually or automatically. For example, the method may further comprise, prior to conveying the one or more heat transfer components to the cleaning station, attaching the one or more heat transfer components to an automated conveyor system configured to traverse the cleaning, nanostructuring, and functionalization stations. The automated conveyer system may be a conveyer belt or another automated transport system known in the art. The heat transfer components may be conveyed to each station individually or in batches. Given that the method is semi-continuous, the one or more heat transfer components may pass through a given station without stopping while undergoing processing or may be halted for processing at a given station, preferably for a short time duration. The conveyor system may be configured to lower or otherwise transport the heat transfer components into vats, drums and/or other chambers as needed during processing.

As illustrated in the schematic of FIG. 1A, the cleaning station may comprise a spray nozzle in fluid communication with the organic solvent, and the cleaning may entail exposing the one or more heat transfer components to a high- or low-pressure spray of the organic solvent. Multiple spray nozzles may be employed if desired for more rapid or thorough cleaning. Also or alternatively, the cleaning station may comprise a vat containing the organic solvent, and the cleaning may comprise submerging the one or more heat transfer components in the organic solvent. The organic solvent may be agitated during the submersion; for example, the vat may comprise a sonicator to induce vibrations that lead to agitation of the solvent and more effective cleaning. Generally speaking, the heat transfer component may be understood to be immersed in the organic solvent during the cleaning step, which may entail being sprayed (e.g., pressure washed) with the organic solvent, or being submerged in the organic solvent, as described above.

Preferably, the one or more heat transfer components are cleaned with more than one organic solvent. In this case, the cleaning station may include more than one vat and/or additional spray nozzle(s) in fluid communication with another organic solvent. The heat transfer component may be immersed in the two or more different organic solvents, preferably sequentially, to effect cleaning. For example, the heat transfer component(s) may be cleaned sequentially with two or more different organic solvents, as illustrated in FIGS. 1A and 1B, which shows sequential exposure of a heat transfer component to a spray of acetone and then to a spray of ethanol. Acetone is particularly useful for degreasing, and the ethanol may help to remove any residue of the acetone. The organic solvent(s) may be reused (e.g., up to three times depending on the contamination level of the heat transfer components being cleaned). When no longer reusable, the organic solvents may be safely disposed of.

After cleaning with the organic solvent(s), the one or more heat transfer components may be rinsed thoroughly with water, more particularly with deionized (DI) water. The rinsing may comprise spraying with water (e.g., pressure washing), as illustrated for example in FIG. 1C, or submerging in water (e.g., in a vat). Although a single spray nozzle is shown in the schematic, it is understood that one or more spray nozzles may be employed for rinsing with a high- or low-pressure spray of water. A large quantity of DI water may be employed during the method, and thus a high capacity DI water generation system, such as a reverse osmosis system, may be required. After rinsing, the one or more heat transfer components may be dried passively by exposure to ambient air or actively by exposure to a pressurized stream of nitrogen gas or air.

Referring now to FIG. 1F, the one or more heat transfer components may then conveyed to a nanostructuring station and submerged in hot water (preferably hot DI water) for a time sufficient for surface oxidation and roughening to occur. It is understood that the hot water may be a hot aqueous solution including water (e.g., deionized water) and one or more additional components. Thus, roughened surfaces comprising nanostructured surface protrusions are formed on the one or more heat transfer components. Typically nonuniform in size and shape, the nanostructured surface protrusions may have a blade-like shape where the length of individual surface protrusions is greater than the width, which may be much greater than the thickness. The length of individual surface protrusions is typically about 1 micron or less. The nanostructured surface protrusions may comprise a metal hydroxide and/or a metal oxide. For example, nanostructured surface protrusions comprising aluminum oxyhydroxide (e.g., boehmite) may result from exposing an aluminum heat transfer component to the hot water treatment. Typically, the submersion takes place for from 5 min to 75 min, and more typically from 5 min to 60 min. During the submersion, the hot water may be maintained at a temperature in a range from 85° C. to 95° C.

The nanostructuring station may comprise a heated vat containing the hot water. Industrial boilers that are heated using gas or electricity may be suitable. In one example, the heated vat may take the form of a stainless steel drum wrapped with heating tape connected to a temperature controller. The vat may be a sufficient size (e.g., 55 gallon or about 208 liter capacity, or larger) to hold a batch of the heat transfer components (e.g., from 6-12 components). After the submersion in hot water, the heat transfer component(s) may undergo a drying process, either passively by ambient air or actively by exposure to a pressurized stream of nitrogen gas or air, as illustrated in FIG. 1G. At this point in the process (after the hot water treatment), surfaces of the heat transfer component(s) are typically hydrophilic.

It may be beneficial to etch or activate surfaces of the heat transfer component(s) prior to the submersion in hot water. Thus, after cleaning and rinsing as described above, the one or more heat transfer components may be conveyed to a microstructuring station and exposed to an acid solution, as illustrated in FIG. 1D. The acid solution may include hydrochloric acid, nitric acid, acetic acid, sulfuric acid and/or hydrofluoric acid. In one example, the acid solution is a 2 M HCl solution. The microstructuring station may include a vat of the acid solution in an enclosure with a ventilation hood, and the heat transfer component(s) may be submerged in the acid solution. The exposure may take place for a period of 10 to 20 minutes, typically. Afterward, the one or more heat transfer components may be rinsed thoroughly with water, preferably DI water, by spraying or submerging, as discussed above and illustrated in FIG. 1E. The acid solution may be drained and replaced with a clean acid solution before use with additional heat transfer components.

After cleaning, optional acid exposure, and nanostructuring (hot water treatment), the one or more heat transfer components may be conveyed to a functionalization station where a hydrophobic coating is applied to the roughened surfaces of the heat transfer component(s). Referring now to FIG. 1H, the functionalization station may include a furnace or other enclosed chamber where the component(s) are exposed to a heated precursor vapor comprising a hydrophobic species. The process, which may be carried out at atmospheric pressure, may be referred to as atmospheric pressure chemical vapor deposition (CVD). The furnace or enclosed chamber may take the form of a large stainless steel drum with a lid. The drum may be wrapped with heating tape connected to a temperature controller, and an industrial grade thermometer may be used to provide accurate temperature readings of the atmosphere inside the drum. The drum may be a sufficient size (e.g., 55 gallon or about 208 liter capacity, or larger) to hold a batch of the heat transfer components (e.g., at least 6-12 components).

The heated precursor vapor may be formed by heating a solution of toluene and a hydrophobic species such as a silane (e.g., heptadecafluoro-(tetrahydrodecyl)-trimethoxysilane (HTMS)) to a suitable temperature, such as 80° C. to 100° C. Typically, a volume ratio of the hydrophobic species to toluene in the solution is from 1:16 to 1:22. During the CVD process, the hydrophobic species is deposited on the nanostructured surface protrusions, and thus a superhydrophobic coating is formed on the one or more heat transfer components. Deposition of the hydrophobic species may take place over a period of typically two to four hours. The superhydrophobic coating, which is typically a silane coating, may be from a monolayer (>1 nm) to tens of nanometers (e.g., about 50 nm) in thickness. Typically, the thickness is from about 2 nm to about 10 nm, or from 2 nm to about 5 nm. The hydrophobic species may deposit (or build up) uniformly and conformally over the nanostructured surface protrusions, and may create a rough surface having a Cassie wetting state that allows water or other liquid droplets to coalesce and lift off the surface. Water droplets accumulate on the coated heat transfer component at reduced levels compared to an untreated component, thus preventing frost formation or significantly reducing frost build-up.

As indicated above, the method is applicable to metal-based components in general that may benefit from a superhydrophobic coating and to heat exchangers in particular. For example, the method may be used to coat fin and tube heat exchangers, shell and tube heat exchangers, double pipe heat exchangers, plate heat exchangers, and condensers, evaporators, and/or boilers. While the semi-continuous method is particularly beneficial for treating large-size, fully-manufactured and assembled heat exchangers, the process is also applicable to unassembled heat exchanger parts and other metal-based components, such as windmill blades, ducts, and refrigerator walls or other parts.

Experimental Details

Prototype System

The simplicity of the coating process motivated the design and fabrication of equipment that could handle much larger samples. Initially, a design that allowed for coating smaller residential heat exchangers (e.g., up to about 36 cm×56 cm×15 cm) was investigated. Based on the success of the smaller design, equipment required to coat much larger heat exchangers (e.g., up to about 56 cm×81 cm×25 cm) was designed and built. Efforts were focused on designing a versatile system that would allow the nanostructuring and functionalization steps of the procedure to be performed at a low cost while maintaining tight control of temperature.

The prototype system can be used to coat up to six heat exchangers, depending on their size. However, the basic technology is scaleable to an industrial level, as described above. To summarize, the method can be performed on heat transfer components that are hung from a conveyor belt in a sealed/semi-sealed room. This way the chemical runoff can be collected and recycled. The evaporated acetone and ethanol can also be reclaimed through condensation. The heat transfer components may be submerged in hot water for a duration from five minutes to typically one hour during the hot water treatment process. The conveyer system that carries the heat exchangers can be easily lowered into vats of hot deionized water. The vats can be very simple industrial boilers that are fired using gas or electricity, preferably with temperature controllers. The heat exchangers can then be placed in an industrial furnace that has the ability to introduce the hydrophobic species during the CVD phase. A vent system can help capture any remaining gaseous chemicals before the next batch of heat exchangers are ready to be placed into the furnace.

Cleaning Procedure

In this example, large-size heat exchangers are cleaned manually. A spray bottle is used to spray acetone and ethanol on the heat exchanger. To ensure thorough cleaning, the heat exchanger was thoroughly sprayed in a preset pattern detailed below. This procedure was applied to heat exchangers of about 0.5 inch to about 1 inch in thickness. (1) Place the heat exchanger in an appropriately sized laboratory tray. The tray may be useful for collecting the cleaning agents for safe disposal. (2) To clean side 1 of the heat exchanger, hold the spray bottle 10-20 cm from the face of the heat exchanger and spray thoroughly so that all the fins are covered the cleaning agent. Hold the bottle at an angle to ensure that the spray hits the fin surfaces directly, and spray from top to bottom and left to right. (3) To clean side 2 of the heat exchanger, flip the heat exchanger and perform step 2 but from the opposite direction. (4) Repeat step 2 in the opposite direction. (5) Repeat step 3 in opposite direction. (6) Rinse the heat exchanger thoroughly with de-ionized water. (7) Dispose of the chemical the safely; it is noted that the acetone and ethanol used in this process can be reused up to 3 times if the heat exchanger is not very dirty.

Design of Boiler and Furnace

In order to make the design more economical, stainless steel drums were selected to serve as both the boiler (for the hot water treatment process) and the furnace (for the chemical vapor deposition process). Stainless steel drums are easy to procure and have high temperature and chemical tolerance. In one example, the system includes 55-gallon drums because the dimensions are sufficient to accommodate a variety of heat exchangers. In addition, heating elements for such drums are commercially available. Multiple (e.g., three in this example) heating tapes (e.g., 1440 Watt Briskheat) are wrapped around each drum. Each of the tapes has a temperature controller with a maximum temperature setting of 400° F. The heating tapes may cover the lower third or two-thirds of the drum surface area, as illustrated in FIGS. 1F and 1H. The temperature controllers are always in contact with the drum. The drum and the heating tape assembly is covered with a high temperature fiberglass insulation jacket that prevents unnecessary heat loss from the drum during the heating process and makes it easier for the operators to handle the drum process as well. A thermowell is welded to a hole that was drilled into the lid of the drum. An industrial grade thermometer is screwed into the thermowell to allow for accurate temperature measurements of the atmosphere inside the drum. The lid's original synthetic rubber (EPDM) gasket is replaced with a high temperature fiberglass gasket. The lid clamp was also replaced with a quick release clamp. The top of the lid is also covered with a removable fiberglass insulation panel. The drum may be placed on a high capacity circular dolly, commercially available and specifically designed for handling 55 gallon drums. Insulation may be placed between the drum and the dolly as well.

Hot Water Treatment—Nanostructuring

The boiler is filled with enough deionized water such that the heat exchangers are covered and that evaporation losses are accounted for. The temperature of the three heating tapes is initially set to 400° F. (approximately 204° C.). This setting is maintained until the temperature of the water reaches 90° C., or till boiling is observed, which typically takes three to six hours depending on volume. The clean heat exchangers are then placed into the hot/boiling water. The water can be allowed to flow into the heat exchangers. In case the internal components need to be protected from water, an option is to fill the heat exchanger with an inert liquid and seal it. The temperature of the controllers is then set to 250° F. (approximately 121° C.). The lid is placed on the drum. The heat exchangers are removed after an hour of treatment. They are dried and drained thoroughly, wrapped carefully in a plastic cover, and stored till they can be coated. The water is not reused; instead, it is allowed to cool and drained using a pump. The drum is then cleaned using a soap solution and a good amount of water. It is then ready for use as a furnace.

Hydrophobic Coating—Chemical Vapor Deposition (CVD)

The heaters are set to 400° F. (approximately 204° C.) and the drum is allowed to reach a temperature of 80° C. The heat exchangers can be kept in the drum during this heating process to evaporate any remaining water from the previous step. A solution of toluene and heptadecafluoro-(tetrahydrodecyl)-trimethoxy silane (HTMS) is measured out in a small beaker and placed in the drum with the heat exchangers once the internal temperature reaches 80° C. The lid is replaced and the sealed carefully using the quick release clamp. The heating tapes are set to 190° F. (approximately 88° C.). The heating tapes are turned off after three hours. In one example, a specific solvent/polymer (toluene/HTMS) volume ratio of 0.053 is used with a total volume of 40 ml (2 ml HTMS to 38 ml toluene) for the 55 gallon drum. This solution can be used to coat six heat exchangers (of 6 m² area each) while maintaining a safety factor of 20. See Tables 1 and 2 below. Chemical vapor deposition has been found to work well from 80° C. to 100° C. The drum is allowed to cool overnight while it is sealed. This allows the remaining toluene and HTMS solution to condense. The heat transfer components at this point in the process may be superhydrophobic. They may be removed from the drum for use. The drum can be cleaned using toluene, acetone, and deionized water, in that order.

TABLE 1
Properties and quantities used for exemplary heat exchangers

| HTMS (exemplary properties and quantities used in examples) | | | | | Area of |
|---|---|---|---|---|---|
| Molecular | | | | | Drum |
| Weight | Density | QTY (ml) | Mass (g) | Moles | (m²) |
| 568.3 | 1.54 | 2 | 3.08 | 0.0054 | 1.56 |

Toluene (19:1)

| | | | | | Total | |
|---|---|---|---|---|---|---|
| | | | | | Volume | V_{drum} |
| MW | Density | QTY (ml) | Mass (g) | Moles | (ml) | (m³) |
| 92.14 | 0.867 | 38 | 32.95 | 0.358 | 40.00 | 0.237 |

| Molar Ratio | | Mass | HTMS/air | Molar | |
|---|---|---|---|---|---|
| (HTMS/Toluene) | Volume ratio | Ratio | (mg/m³) | ratio⁻¹ | Vol ratio⁻¹ |
| 0.015 | 0.053 | 0.093 | 12983.73 | 65.98 | 19 |

| Microchannel heat exchangers | | | | | | |
|---|---|---|---|---|---|---|
| Heat exchanger | HTMS | Limiting | Volume | Volume of HTMS required | | |
| area | thickness | volume | of HTMS | with Safety Factor | | |
| (m²) | (measured, m) | (m\hat{ }3) | (ml) | 5 | 10 | 20 |
| 6 | 2.594E−09 | 1.960E−08 | 1.960E−02 | 0.10 | 0.20 | 0.39 |
| Number of heat | | | | | | |
| exchangers | | | | | | |
| that can fit in | | | | | | |
| the drum | | | | | | |
| 6 | 2.594E−09 | 9.742E−08 | 9.742E−02 | 0.49 | 0.97 | 1.95 |
| | | | Solution | 9.74 | 19.48 | 38.97 |
| | | | Volume | | | |
| | | | (ml) | | | |

TABLE 2
Safety factors
36 m² coating area

| Safety | Solution Volume |
|---|---|
| Factor | (ml) |
| 5 | 9.74 |
| 10 | 19.48 |
| 20 | 38.97 |

Multiple heat exchangers, ranging from automotive to residential evaporators and condensers from different commercial manufacturers have been coated using the inventive process. Some grades of aluminum may be resistant to the growth of the boehmite (which provides roughness for creating Cassie-Baxter droplet states) during the hot water treatment procedure. For those grades, an additional acid treatment, as described above (e.g., 2 M HCl for 15 minutes), has been shown to be beneficial.

Durability and Reliability

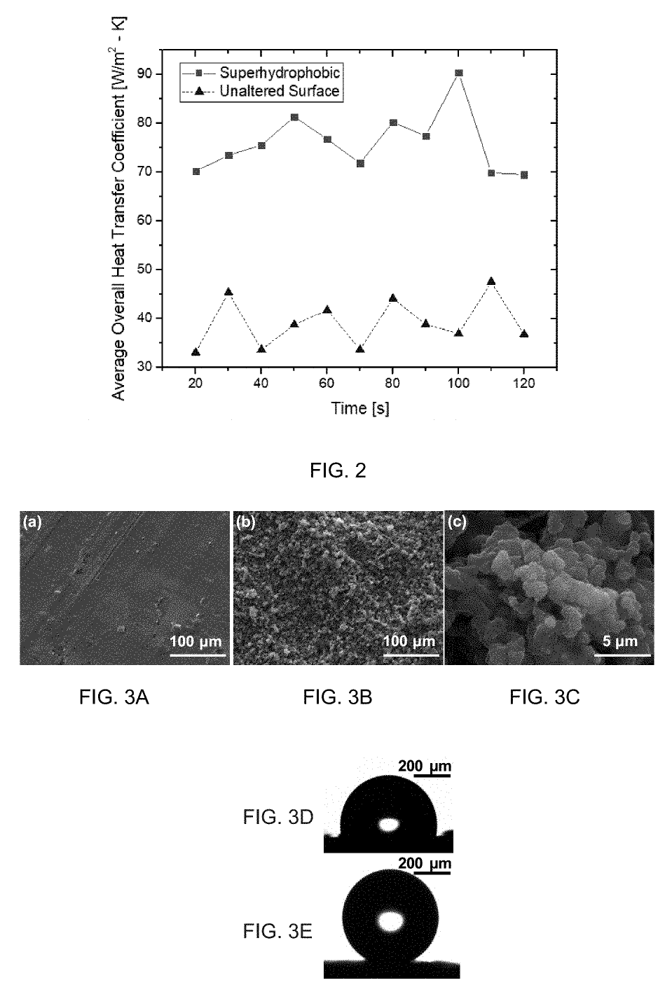

The coated heat exchangers have proved to be extremely durable. Heat exchangers coated one year ago have shown consistent results over multiple testing cycles. In addition, heat transfer experiments designed to induce condensation show a significant improvement in the average overall heat transfer coefficient for a superhydrophobic-coated heat exchanger compared to a heat exchanger with an unaltered surface, as can be seen from the data of FIG. 2.

Frost Characteristics and Heat Transfer

In a further investigation, the inventive process was applied to a decimeter-scale, fully-assembled fin and tube heat exchanger, and the frosting characteristics and heat transfer performance were evaluated and compared with an unaltered heat exchanger and with a superhydrophilic heat exchanger. The heat exchangers were procured from Heatcraft Inc., USA. The tubes are made of copper and the fins are made of aluminum. The fins are brazed onto the 9.53 mm outer diameter copper tubes which make 12 passes through the heat exchanger in a staggered formation. The fin pitch is 2.85 mm and the thickness of each fin is ˜0.25 mm. The length, height, and depth of the heat exchanger are 25.5 cm, 15.2 cm and 2.5 cm, respectively.

In this investigation, two of the heat exchangers were sequentially submerged in acetone, ethanol and deionized water to clean the external surface. They were then exposed to a 2-molar hydrochloric acid solution to create microscale roughness features and placed in a 90° C. de-ionized water bath for one hour to generate a layer of aluminum oxy-hydroxide (boehmite). This process results in a surface with both micro- and nanoscale roughness features, which help promote hydrophilicity. One of the heat exchangers was set aside at this time to remain hydrophilic for characterization and testing. A conformal 2.5 nm thick layer of HTMS was deposited on the other heat exchanger surface using chemical vapor deposition at atmospheric pressure to produce a superhydrophobic surface. The conformal low surface energy coating in addition to the surface roughness promotes the formation of Cassie-Baxter type droplets during condensation. Scanning electron microscopy (SEM) images of the coated surface are shown in FIGS. 3A-3C at two different scales to clearly show the roughness features. Additionally, images of water droplets on the unaltered and superhydrophobic surfaces are shown in FIGS. 3D and 3E, respectively.

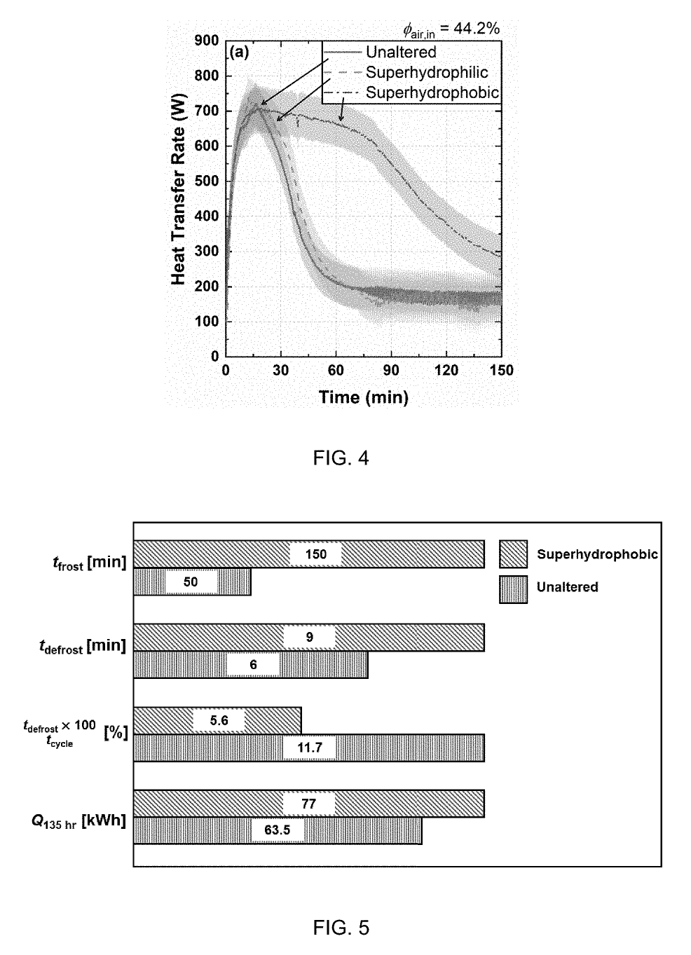

Tests were carried out to evaluate frost accumulation and heat transfer. Frost formation on a heat exchanger ultimately reduces the heat transfer rate because of the increased thermal resistance across the ice layer. The total heat transfer rates of the unaltered, superhydrophilic and superhydrophobic heat exchangers when the coolant enters at −9.6° C.±0.1° C. and the air enters at 47.4° C.±2% are presented in FIG. 4. Frost begins to form on the uncoated and superhydrophilic heat exchangers after about 20 minutes, propagates across the heat exchanger face, and reduces the total heat transfer rate by about 75%. Frost formation is significantly delayed and propagates slower in the superhydrophobic heat exchanger, which allows the heat exchanger to maintain a higher total heat transfer rate for a longer period and reduces the slope of the performance decline. The superhydrophobic heat exchanger supports a heat transfer rate above 350 W (50% of the maximum capacity) for 126 minutes, about 3.1 times longer than its unaltered and hydrophilic counterparts.

Results of an energy analysis for both the uncoated and superhydrophobic heat exchangers are shown in FIG. 5, assuming the ambient relative humidity is about 50% and the inlet coolant temperature is about −10° C. The superhydrophobic heat exchanger shows a 1.2 times increase in heat transfer and 50% decrease in defrosting time over a period of 148 hours. It is assumed here that the defrost cycle in a real system will occur when the heat transfer rate reaches 300 W. 148 hours is the time required for both the uncoated and superhydrophobic heat exchangers to finish a whole number of cycles (cumulative frosting+defrosting time). Although the single cycle defrost time for the superhydrophobic heat exchanger is longer than the unaltered heat exchanger, the overall defrosting time for the superhydrophobic sample is lower because of the reduced frequency of defrosting (56 defrosting cycles for the superhydrophobic heat exchanger versus 159 cycles for the unaltered heat exchanger). This analysis does not include the extra energy required to evaporate the water retained on the uncoated heat exchangers. Retained water can decrease the performance of consequent frosting cycles depending on the geometry of the heat exchanger.

Although the present invention has been described in considerable detail with reference to certain embodiments thereof, other embodiments are possible without departing from the present invention. The spirit and scope of the appended claims should not be limited, therefore, to the description of the preferred embodiments contained herein. All embodiments that come within the meaning of the claims, either literally or by equivalence, are intended to be embraced therein.

Furthermore, the advantages described above are not necessarily the only advantages of the invention, and it is not necessarily expected that all of the described advantages will be achieved with every embodiment of the invention.

1. A method of coating heat transfer components to impart superhydrophobicity, the method comprising:
conveying one or more heat transfer components to a cleaning station and cleaning the one or more heat transfer components with an organic solvent;
after the cleaning, conveying the one or more heat transfer components to a nanostructuring station and immersing the one or more heat transfer components in hot water for surface oxidation and roughening; and
after the immersion in hot water, conveying the one or more heat transfer components to a functionalization station and exposing the one or more heat transfer components to a heated precursor vapor comprising a hydrophobic species,
wherein, during the exposure, the hydrophobic species is deposited on roughened surfaces of the one or more heat transfer components, thereby forming a superhydrophobic coating.

2. The method of claim 1, further comprising, prior to conveying the one or more heat transfer components to the cleaning station, attaching the one or more heat transfer components to an automated conveyor system positioned to traverse the cleaning, nanostructuring, and functionalization stations.

3. The method of claim 1, wherein the cleaning station comprises a spray nozzle in fluid communication with the organic solvent, the cleaning comprising spraying the organic solvent onto the one or more heat transfer components, or
wherein the cleaning station comprises a vat containing the organic solvent, the cleaning comprising submerging the one or more heat transfer components in the organic solvent.

4. The method of claim 3, wherein the one or more heat transfer components are cleaned with more than one organic solvent, the cleaning station comprising more than one vat and/or an additional spray nozzle in fluid communication with a different organic solvent.

5. The method of claim 1, wherein the one or more heat transfer components are cleaned sequentially with acetone and ethanol.

6. The method of claim 1, further comprising rinsing the one or more heat transfer components with water after the cleaning.

7. The method of claim 1, wherein the nanostructuring station comprises a heated vat containing the hot water, the one or more heat transfer components being submerged in the hot water for surface oxidation and roughening.

8. The method of claim 7, wherein the heated vat comprises a stainless steel drum wrapped with heating tape connected to a temperature controller.

9. The method of claim 1, wherein the hot water comprises hot deionized water maintained at a temperature in a range from 85° C. to 95° C.

10. The method of claim 1, wherein the roughened surfaces comprise nanostructured surface protrusions comprising a metal hydroxide and/or a metal oxide.

11. The method of claim 10, wherein the nanostructured surface protrusions comprise a blade-like shape.

12. The method of claim 1, further comprising, prior to the immersion in hot water, conveying the one or more heat transfer components to a microstructuring station, and exposing the one or more heat transfer components to an acid solution.

13. The method of claim 1, wherein the exposure to the heated precursor vapor takes place in an enclosed chamber where the heated precursor vapor is maintained at a temperature in a range from about 80° C. to about 100° C.

14. The method of claim 13, wherein the enclosed chamber comprises a stainless steel drum with a lid, the stainless steel drum being wrapped with heating tape connected to a temperature controller.

15. The method of claim 1, wherein the heated precursor vapor comprises a silane and toluene, the silane being the hydrophobic species.

16. The method of claim 1, wherein the one or more heat transfer components are fully-assembled heat exchangers.

17. The method of claim 1, wherein, individually, the one or more heat transfer components have a length exceeding 25 cm.

18. The method of claim 17, wherein the length exceeds 50 cm.

19. The method of claim 1, wherein the one or more heat transfer components comprise one or more metals selected from the group consisting of: aluminum, titanium, iron, chromium, nickel, molybdenum, and copper.

20. The method of claim 1, further comprising, prior to conveying the one or more heat transfer components to the cleaning station, attaching the one or more heat transfer components to an automated conveyor system positioned to traverse the cleaning, nanostructuring, and functionalization stations,
wherein the one or more heat transfer components are cleaned sequentially with acetone and ethanol, and further comprising rinsing the one or more heat transfer components with water after the cleaning,
wherein the nanostructuring station comprises a heated vat containing the hot water, the one or more heat transfer components being submerged in the hot water for surface oxidation and roughening, the hot water comprising hot deionized water maintained at a temperature in a range from 85° C. to 95° C.,
further comprising, prior to the submersion in hot water, conveying the one or more heat transfer components to a microstructuring station, and exposing the one or more heat transfer components to an acid solution, and
wherein the exposure to the heated precursor vapor takes place in an enclosed chamber where the heated precursor vapor is maintained at a temperature in a range from about 80° C. to about 100° C.
